(19) United States
(12) Patent Application Publication
(10) Pub. No.: US 2004/0090248 A1
(43) Pub. Date: May 13, 2004

(54) Programmable timing generator with offset and width control using delay lock loop

(75) Inventors: David Charneski, Hilton, NY (US); Edward P. Lawler, Fairport, NY (US)

Correspondence Address: Thomas H. Close, Patent Legal Staff, Eastman Kodak Company, 343 State Street, Rochester, NY, 14650-2201, US

(73) Assignee: Eastman Kodak Company

(21) Appl. No.: 10/637,401

(22) Filed: Aug. 8, 2003

Related U.S. Application Data
(60) Provisional application No. 60/412,235, filed on Sep. 20, 2002.

(51) Int. Cl. H03K 3/00

(52) U.S. Cl. 327/99

(57) ABSTRACT

A clock generator for providing programmable control of an output clock, the clock generator includes a mechanism for creating a plurality of clocks offset in phase; two programmable selectors for selecting two clocks from the plurality of clocks; and logic for combining the two selected clocks to create an output clock with any combination of offset, if any, and width.

### CROSS REFERENCE TO RELATED APPLICATIONS

The present application is related to U.S. Pat. No. 5,982,428, issued on Nov. 9, 1999, by Chameski, et al, entitled PROGRAMMABLE CLOCK GENERATOR FOR AN IMAGING DEVICE; and U.S. Pat. No. 6,246,275, issued on Jun. 12, 2001, by Wodnicki, et al., entitled MULTIPHASE PROGRAMMABLE CLOCK GENERATOR.

### FIELD OF THE INVENTION

This invention relates generally to electronic imaging systems and, more particularly, to formation of programmable periodic waveforms for electronic imaging systems.

### BACKGROUND OF THE INVENTION

Current methods for forming periodic waveforms include, for example, U.S. Pat. No. 5,982,428 entitled “Programmable Clock Generator For An Imaging Device” by Charneski, et al. U.S. Pat. No. 5,982,428 requires that, in order to get width and offset positioning resolution of (1/N) * T_{pix—clk}, an input clock having a frequency of (N/2) * f_{pix—clk} is required.

U.S. Pat. No. 6,246,275 entitled “Multi-Phase Programmable Clock Generator” by Wodnicki, et al. discloses using a shift register to circulate a bit pattern in order to generate various clocking waveforms with programmable offset and width.

Although the currently known methods and apparatus are satisfactory, they include drawbacks. For example, U.S. Pat. No. 6,246,275 does not use higher frequency multiples of a base input clock to generate offset and width increments in sub-intervals of the base input clock period. It also makes no attempt at reducing this high frequency clock multiplication factor or combining shift register outputs to form output clocks. Furthermore, it does not use DLL or PLL technology to form a plurality of clocks of differing phases which are later combined to form an output clock with high resolution programmable offset and width.

Consequently, a need exists for a method and apparatus with finer offset and width resolution, which is not related to input clock frequency, by using a delay lock loop (DLL) to generate phase offsets. Offset and width resolution is only limited by jitter in the DLL. In addition, a need exists for a NOR/NAND/MULTIPLEXER structure to allow generation of pulses with greater than 50% duty cycle.

### SUMMARY OF THE INVENTION

The present invention is directed to overcoming one or more of the problems set forth above. Briefly summarized, according to one aspect of the present invention, the invention resides in a clock generator for providing programmable control of an output clock, the clock generator comprising (a) a mechanism for creating a plurality of clocks offset in phase; (b) two programmable selectors for selecting two clocks from the plurality of clocks; and (c) logic for combining the two selected clocks to create an output clock with any combination of offset, if any, and width.

Advantageous Effect Of The Invention

The present invention has the following advantages. It eliminates the need for a high frequency input clock for generation of fine resolution offset and width positioning. This is accomplished through the use of delay lock loop (DLL) technology resulting in offset and width resolution that is largely independent of input clock frequency. For offset and width selections of N taps within one output clock period, the present invention allows the use of DLLs with N/2 taps, thus minimizing jitter and maximizing overall accuracy and stability within the DLL, while also conserving space in the integrated circuit. The present invention allows generation of pulses with greater than 50% duty cycle and allows inversion of the output waveform. Finally, the present invention provides glitch-free enabling of the output waveform.

### BRIEF DESCRIPTION OF THE DRAWINGS

FIG. 1 is a block diagram of the preferred embodiment of the present invention;

FIG. 2 is a timing diagram showing the plurality of clocks generated by the DLL of the preferred embodiment in FIG. 1;

FIG. 3 is a timing diagram referencing aspects of FIG. 1 describing an example of output clock pulse generation with a duty cycle of less than 50%; and

FIG. 4 is a timing diagram referencing aspects of FIG. 1 to describe an example of output clock pulse generation with a duty cycle of greater than 50%.

### DETAILED DESCRIPTION OF THE INVENTION

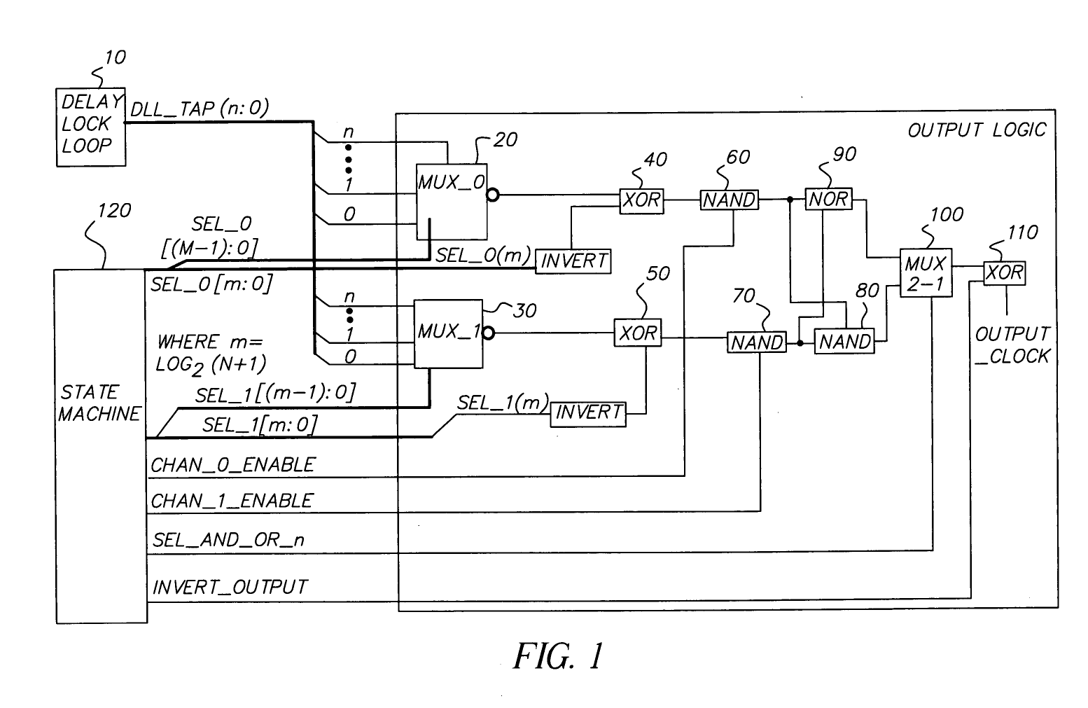

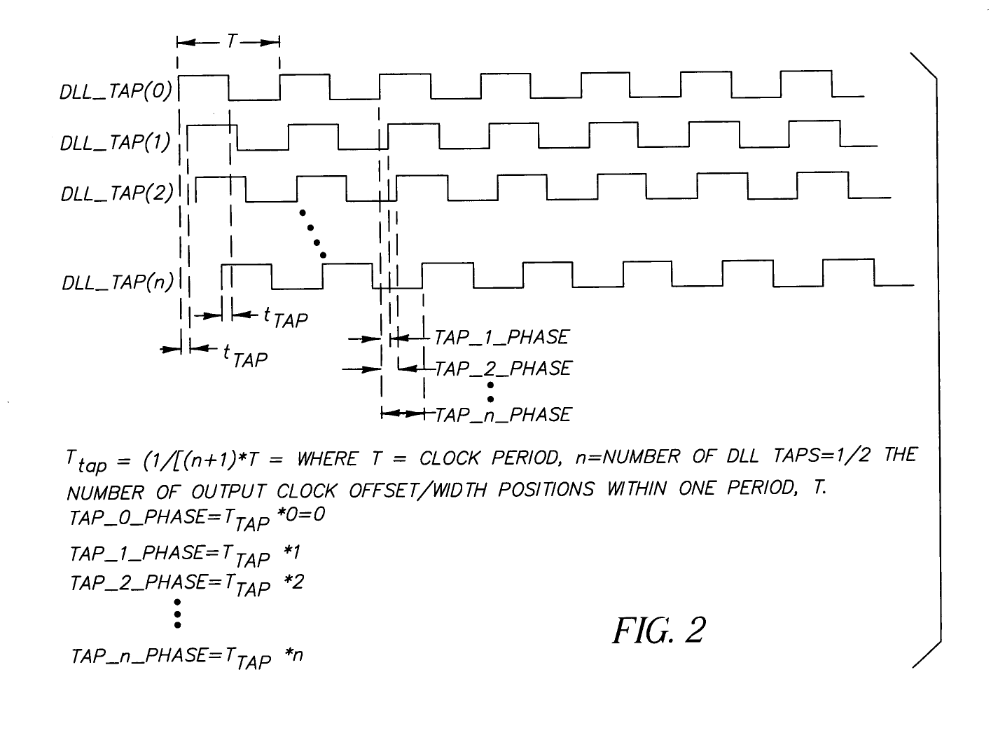

In FIG. 1, a delay lock loop (DLL) 10 provides a plurality of continuously operating clocks or “taps”, dll_tap(n:0), (see FIG. 2) that have phase offsets which differ by [(1/((n+1)*2)] of the DLL clock period, T, such that tap_{—}0_phase<tap_{—}1_phase<tap_2_phase<. . . tap_n_phase, where n=[(total number of DLL taps)−1]. As illustrated in FIG. 2, it is important to note that the phase shifts provided by the DLL taps only span the first half of the clock period. Phase shifts spanning the last half of the clock period are created by inverting the DLL taps, as will be described.

The DLL taps, dll_tap(n:0), are connected to multiplexer 20, MUX_0, and multiplexer 30, MUX_1. Each of these multiplexers 20 and 30 independently selects one of the plurality of taps, thus forming two distinct channels through which these taps flow. This allows for the transfer of a different DLL tap to the output of each multiplexer and is the way in which output_clock is eventually formed, as will be described.

The output of multiplexer 20 is connected to an input of EXCLUSIVE OR (XOR) gate 40, while the other input of XOR 40 is connected to the most significant bit of the MUX_0 20 select bus, sel_{—}0(m). In a similar fashion, the output of MUX_1 30 is connected to an input of EXCLUSIVE OR (XOR) 50, while the other input of XOR 50 is connected to the most significant bit of the MUX_1 30 select bus, sel_{—}1(m).

Considering only the channel 0 path for a moment, the following tap-doubling functionality is described. Referring to FIGS. 1 and 2, when sel_{—}0(m)=‘0’, the input to the XOR 40 is ‘0’, causing the output of XOR 40 to be equal to the output of multiplexer 20 MUX_0. When sel_{—}0(m)=‘1’, the input to the XOR 40 is ‘1’, causing the output of XOR 40 to be the inverse of the output of multiplexer 20 MUX_0. This inversion operation causes a 180 degree phase shift in the DLL tap feeding channel 0 and provides the mechanism for generating the remaining DLL taps for the second half of the clock period, T. Therefore, with sel_{—}0(m)=‘1’ and sel_{—}0[(m−1):0]=0(decimal), dll_tap(0) is selected by multiplexer 20 MUX_0 and is inverted by XOR 40, thus forming dll_tap(n+1) at the output of XOR 40. With sel_{—}0(m)=‘1’ and sel_{—}0[(m−1):0]=1(decimal), dll_tap(l) is selected by MUX_0 20 and is inverted by XOR 40, thus forming dll_tap(n+2) at the output of XOR, and so on up to dll_tap(2n+1). In this way, the number of DLL taps have effectively been doubled, thus allowing the use of a DLL with only half the required number of taps. This minimizes jitter and maximizes overall accuracy and stability within the DLL, while also conserving space in the integrated circuit.

The preceding description of the tap-doubling logic for channel 0 applies in a similar manner to channel 1. Thus, the full (2n+1) DLL taps can also be generated at the output of XOR 50.

Considering only the channel 0 path for a moment, the following enable and disable functionality is described. Referring to FIG. 1, the output of XOR 40 is connected to an input of NAND 60, while the other input to NAND 60 is connected to chan_{—}0_enable. When chan_{—}0_enable=‘0’, the output of NAND 60 (I) is held at ‘1’, thus effectively disabling the clocking action of the DLL tap selected by MIX_{—}0 20 (C). When chan_{—}0_enable=‘1’, the output of NAND 60 follows the output of XOR 40 (G), thus allowing the clocking action of the DLL tap selected by MUX_0 20 (C) to flow freely to the next stage of logic. The same enable and disable functionality is provided in channel 1 via NAND 70 and chan_1_enable. Together, chan_{—}0_enable and chan_1_enable can be used to turn the output-clock ON and OFF. It is also possible to pass any DLL tap straight through the OUTPUT_LOGIC to output_clock by enabling channel 0 (chan_{—}0_enable=‘1’) and disabling channel I (chan_1_enable=‘0’). This capability is useful for test purposes and for generating a 50% duty cycle clock at output-clock (assuming the DLL taps are 50% duty cycle).

The outputs of NAND 60 and NAND 70 are connected to the inputs of NAND 80, which is used to generate pulses that are less than 50% duty cycle. The outputs of NAND 60 and NAND 70 are also connected to the inputs of NOR 90, which is used to generate pulses that are greater than 50% duty cycle.

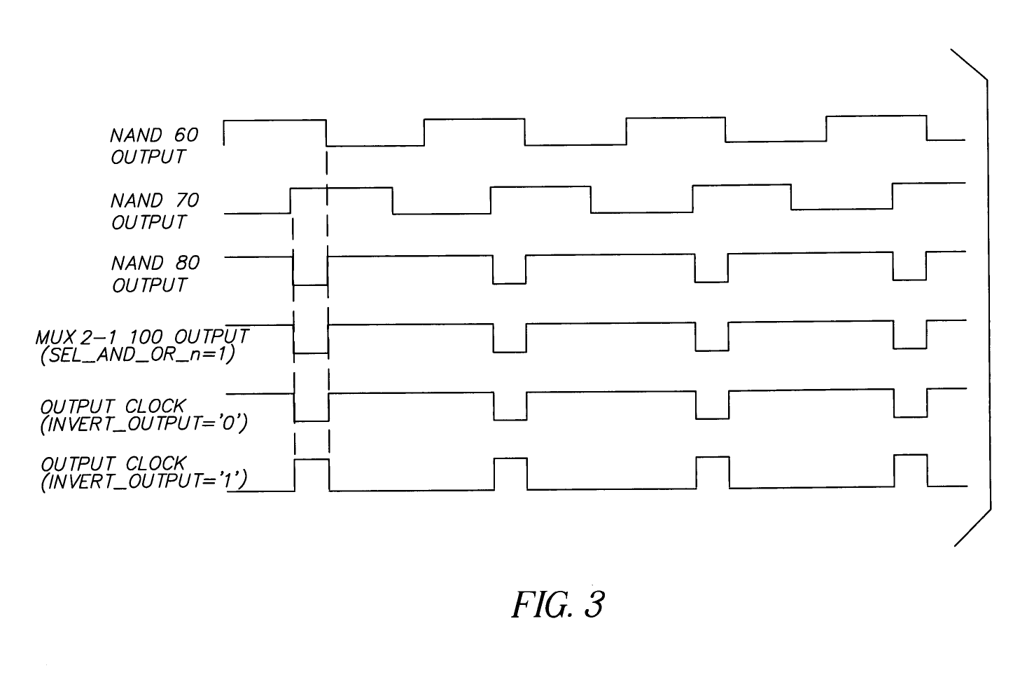

The generation of pulses of less than 50% duty (through NAND 80) will be described first. Referring to FIGS. 1 and 3, the DLL tap selected through NAND 70 is greater than that selected through NAND 60, thus forming the periodic waveform shown at the output of NAND 80. Whenever both inputs to NAND 80 are a logic ‘1’, the output is a logic ‘0’. Whenever one or both inputs to NAND 80 are a logic ‘0’, the output is a logic ‘1’. Referring to FIG. 1, the output of NAND 80 is connected to one of the inputs of MUX 2-1 100. The other input to MUX 2-1 100 is connected to the output of NOR 90, whose operation is described below. When sel_and_or_n=‘1’, the output of MUX 2-1 100 follows the output of NAND 80, as shown in FIG. 3. The output of MUX 2-1 100 is connected to one of the inputs of XOR 110. The other input to XOR 110 is connected to invert_output. When invert_output=‘0’, output_clock follows the output of MUX 2-1 100, as shown in FIG. 3. Note also in FIG. 3 that when invert_output=‘1’, the output_clock waveform is inverted.

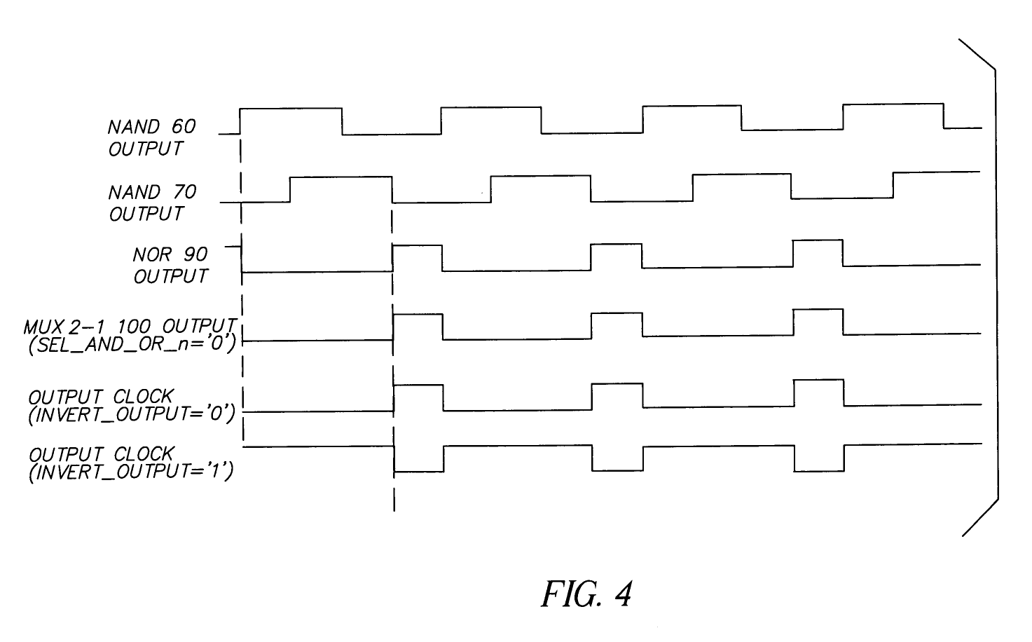

For generation of output_clock pulses that are greater than 50% duty cycle the NOR 90 path is selected by MUX 2-1 100 by setting sel_and_or_n=‘0’. The corresponding waveforms for the NOR 90 path are shown in FIG. 4.

The STATE MACHINE 120 can be designed to control the inputs and, therefore, the previously described functionality of OUTPUT_LOGIC (0). In this way, a flexible and powerful clock generation circuit is realized.

The invention has been described with reference to a preferred embodiment. However, it will be appreciated that variations and modifications can be effected by a person of ordinary skill in the art without departing from the scope of the invention.

### PARTS LIST

10 delay lock loop (DLL)

20 multiplexer (MUX_0)

30 multiplexer (MUX_1)

40 XOR

50 XOR

60 NAND

70 NAND

80 NAND

90 NOR

100 multiplexer (MUX 2-1)

110 XOR

120 state machine

What is claimed is:

1. A clock generator for providing programmable control of an output clock, the clock generator comprising:
(a) a mechanism for creating a plurality of clocks offset in phase;
(b) two programmable selectors for selecting two clocks from the plurality of clocks; and
(c) logic for combining the two selected clocks to create an output clock with any combination of offset, if any, and width.

2. The clock generator as in claim 1 further comprising a logic element for starting and stopping the output clock.

3. The clock generator as in claim I further comprising a logic element for starting and stopping the two selected clocks from the programmable selectors.

4. The clock generator as in claim 1 further comprising a logic element for starting and stopping the plurality of clocks.

5. The clock generator as in claim 1, wherein the mechanism for creating the plurality of clocks includes a delay lock loop.

6. The clock generator as in claim 1, wherein the mechanism for creating the plurality of clocks includes a programmable clock generator and at least one shift register.

7. A clock generator for providing programmable control of an output clock, the clock generator comprising:
(a) a mechanism for creating a plurality of clocks offset in phase;
(b) a programmable selector for selecting a clock from the plurality of clocks; and
(c) logic for controlling the selected clock to create an output clock with any offset.

8. The clock generator as in claim 7 further comprising a logic element for starting and stopping the plurality of clocks.

9. The clock generator as in claim 7, wherein the mechanism for creating the plurality of clocks includes a delay lock loop.

10. The clock generator as in claim 7, wherein the mechanism for creating the plurality of clocks includes a programmable clock generator and at least one shift register.
